(19) United States
(12) Patent Application Publication
(10) Pub. No.: US 2001/0017408 A1
(43) Pub. Date: Aug. 30, 2001

(54) Semiconductor package

(75) Inventor: Mikio Baba, Tokyo (JP)

Correspondence Address: YOUNG & THOMPSON, 745 SOUTH 23RD STREET 2ND FLOOR, ARLINGTON, VA, 22202

(73) Assignee: NEC CORPORATION

(21) Appl. No.: 09/791,801

(22) Filed: Feb. 26, 2001

(30) Foreign Application Priority Data
Feb. 28, 2000 (JP) 51223/2000

(51) Int. Cl. H01L 23/34

(52) U.S. Cl. 257/713; 257/712

(57) ABSTRACT

The semiconductor package according to the present invention includes an insulating substrate, a reinforcing plate formed in an annular form in the periphery on the surface of the insulating substrate, a semiconductor chip installed face down on the insulating substrate, a reinforcing plate, and a heat radiating plate formed over the semiconductor chip, wherein the height of the back face of the semiconductor chip as measured from the surface of the insulating substrate is larger than the height of the surface of the reinforcing plate, which is brought into contact with the radiating plate, as measured from the surface of the insulating substrate.

### BACKGROUND OF THE INVENTION

1. Field of the Invention

The present invention relates to a semiconductor package, and more particularly to a semiconductor package in which a semiconductor chip is mounted on an insulating substrate with a bonded reinforcing plate, and a heat radiating plate is attached to the back face of the semiconductor chip.

2. Description of the Prior Art

Heretofore, a semiconductor device of the above kind has, as shown in the flip-chip type BGA in FIG. 3, a flip-chip type semiconductor chip 2 having solder bumps mounted face down on an insulating substrate 1 equipped with a copper reinforcing plate, thereby the semiconductor chip 2 and the substrate 1 are connected electrically through welded connection of solder bumps 3 of the semiconductor chip 2 and preliminary solder (not shown) of the substrate 1. Here, the gap between the flip-chip type semiconductor chip 2 and the substrate 1 is 140 μm, the pitch of the bumps is 240 μm, the number of bumps is 3000, the chip size is a square of side 15 mm, and the thickness of the chip is 725 μm. The height of the back face of the semiconductor chip 2 from the surface of the substrate 1 is 890 μm including the warp of the semiconductor chip 2. In the meantime, the height of the surface of the reinforcing plate 5 from the surface of the substrate 1 is 910 μm including the thickness of an adhesive 4 filled in the space between the substrate 1 and the reinforcing plate 5. Therefore, the height of the reinforcing plate 5 is larger than the height of the semiconductor chip 2. An appropriate amount of an epoxy resin 6 is filled as an under-fill resin in a solder connection part between the semiconductor chip 2 of flip-chip type and the insulating substrate 1. Then, the under-fill resin 6 is cured at a proper temperature (around 150° C. in this example).

Next, the back face of the semiconductor chip is coated with a silver paste 7 having electrical conductivity as an adhesive resin. In addition, the upper part of the reinforcing plate 5 of the insulating substrate 1 is also coated with a connecting resin 8. Following that, a heat radiating plate 9 made of copper is arranged over the back face of the semiconductor chip and the upper part of the reinforcing plate to fix the radiating plate 9 firmly through curing of the resin. After that, solder balls 10 are mounted on the back face of the insulating substrate where the semiconductor chip is not mounted, completing a flip-chip type BGA package.

When a flip-chip BGA package is manufactured according to the conventional method described above, the difference between the height of the back face of the semiconductor chip and the height of the surface of the reinforcing plate, both measured from the substrate surface, is 20 μm with a result that the height of the reinforcing plate being larger than the height of the semiconductor chip. When the dispersion (±25 μm) in the height difference due to manufacture in attaching the reinforcing plate to the substrate is taken into consideration, there arises a case in which the height of the reinforcing plate is larger than the height of the semiconductor chip by more than 40 μm. If the radiating plate is attached in this state, after a scrubbing work for bonding the radiating plate to the back face of the semiconductor chip, the radiating plate 9 which has been warped in a concave form due to scrubbing as shown in FIG. 4, is warped in a convex form as a reaction to the scrubbing. As a result, the resin which has been spread uniformly over the back face of the semiconductor chip is drawn to the central part of the semiconductor chip where the thickness of the silver paste resin is increased (to about 40 to 80 μm), making it difficult to obtain a desired thermal resistance.

Moreover, when the height of the reinforcing plate is 760 μm, too low compared with the height of the semiconductor chip, the gap between the radiating plate and the reinforcing plate becomes too large, making it liable to develop a drawback in which the radiating plate above the reinforcing plate is deformed depending upon the manner of handling the package.

Furthermore, when the height of the semiconductor chip is 890 μm and the height of the reinforcing plate is in the range of 870 to 890 μm, there arises a case in which the height of the reinforcing plate becomes larger than the height of the semiconductor chip, when the dispersion during the bonding process of the reinforcing plate as mentioned above and other dispersions during the manufacture are taken into consideration.

### BRIEF SUMMARY OF THE INVENTION

Object of the Invention

It is the object of the present invention to provide a semiconductor package which makes it possible to facilitate a scrubbing work in attaching a radiating plate, secure uniform wettability of the back face of a semiconductor chip to a silver paste adhesive, reduce the thickness of the resin to less than 50 μm, and obtain a flip-chip package of low thermal resistance.

### SUMMARY OF THE INVENTION

The semiconductor package according to the present invention comprises an insulating substrate, a reinforcing plate provided in an annular form in the periphery on the surface of the insulating substrate, a semiconductor chip installed face down on the surface of the insulating substrate, a reinforcing plate, and a radiating plate installed on the semiconductor chip, wherein the height of the back face of the semiconductor chip as measured from the surface of the insulating substrate is larger than the height of the surface of the reinforcing plate, which is brought into contact with the radiating plate, as measured from the surface of the insulating substrate.

### BRIEF DESCRIPTION OF THE DRAWINGS

The above-mentioned and other objects, features, and advantages of this invention will become more apparent by reference to the following detailed description of the invention taken in conjunction with the accompanying drawings, wherein:

FIG. 1 is a sectional view of the package showing a first embodiment of the present invention;

FIG. 2 is a sectional view of the package showing a second embodiment of the invention;

FIG. 3 is a sectional view of a conventional package; and

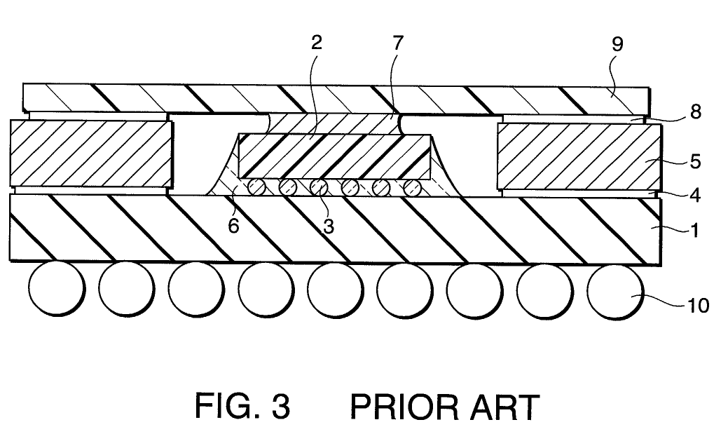

FIG. 4 is a sectional view of the package when the height of the semiconductor chip is too large in a conventional example.

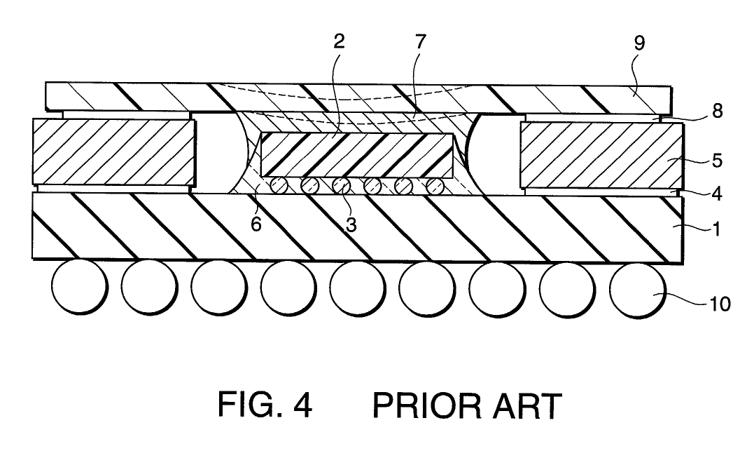

### DETAILED DESCRIPTION OF THE INVENTION

Referring to the drawings, the present invention will be described in the following.

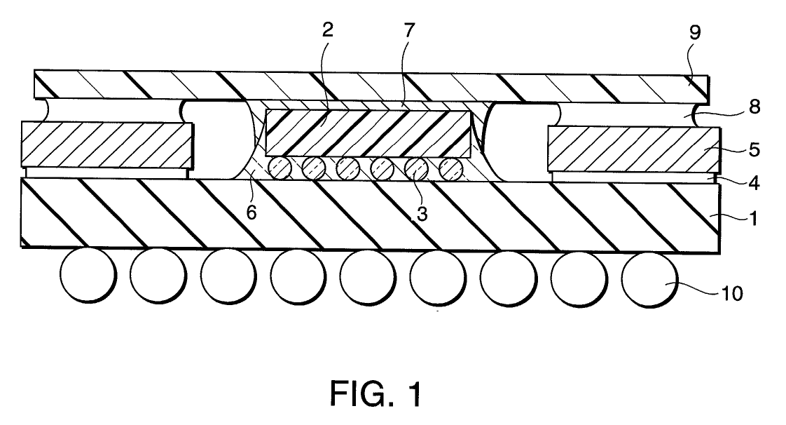

FIG. 1 is a sectional view showing the configuration of a first embodiment of the invention. As shown in FIG. 1, in this embodiment, a copper reinforcing plate 5 is formed in annular form in the periphery on the surface of an insulating substrate 1, a flip-chip type semiconductor chip 2 having solder bumps 3 is mounted face down on the insulating substrate, and the semiconductor chip 2 and the substrate 1 are connected electrically through welding connection of the solder bumps 3 of the semiconductor chip 2 and preliminary solder (not shown) of the substrate 1. The gap between the flip-chip type semiconductor chip 2 and the substrate 1 is 140 μm, the pitch of the bumps is 240 μm, the number of bumps is 3000, the size of the semiconductor chip is a square with a side of 15 mm, and the thickness of the chip is 725 μm. The height of the back face of the semiconductor chip from the surface of the substrate 1 is 890 μm including the warp of the semiconductor chip. In the meantime, the height of the surface of the reinforcing plate brought into contact with a radiating plate measured from the surface of the substrate 1 is set at 820 μm including the thickness of an adhesive 4 injected to the space between the substrate 1 and the reinforcing plate 5. An appropriate amount of an epoxy resin is filled as an under-fill resin in the solder connection part formed by the space between the flip-chip type semiconductor chip 2 and the insulating substrate 1. Then, the under-fill resin 6 is cured at a proper temperature (around 150° C. in this example).

Next, the back face of the semiconductor chip 2 is coated with an electrically conductive silver paste 7 as an adhesive resin. In addition, the upper part of the reinforcing plate 5 of the insulating substrate 1 is also coated with an adhesive resin 8 Following that, a radiating plate 9 made of copper is arranged over the back face of the semiconductor chip 2 and the upper part of the reinforcing plate 5 to attach the radiating plate 9 to them by curing the resin. After that, solder balls 10 are mounted on the back face of the insulating substrate where the semiconductor chip is not mounted, obtaining a BGA package of flip-chip type.

In the semiconductor device of this invention, in order to control the thickness of the adhesive injected between the back face of the semiconductor chip and the radiating plate to be less than 50 μm, it is necessary to form the device such that the difference between the height of the back face of the semiconductor chip from the substrate surface and the height of the reinforcing plate from the substrate surface is 75±50 μm, the height of the back face of the semiconductor chip being the larger.

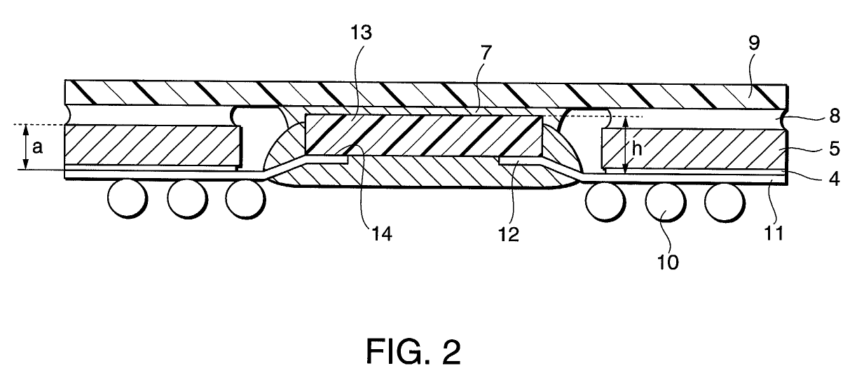

FIG. 2 is a sectional view showing the configuration of a second embodiment of this invention. As shown in FIG. 2, this embodiment refers to a tape type BGA package. In FIG. 2, the lengths h and a satisfy the condition h−a=75±50 μm. An inner lead 12 connected to an insulating tape 11 of a TAB to which is attached a copper annular reinforcing plate 5, and a pad 14 provided on the surface of a semiconductor chip 13 are connected electrically by bonding. The semiconductor chip 13 and the solder balls 10 are connected electrically via the inner lead 12. The tape thickness is 125 μm, the chip size is a square with a side of 1 mm, and the chip thickness is 350 μm. The height of the back face of the semiconductor chip 13 from the surface of the tape 11 is 520 μm including the warp of the semiconductor chip 13. In the meantime, the height of the surface of the reinforcing plate 5 from the surface of the tape 11 is 440 μm including the thickness of the adhesive 4 given between the tape 11 and the reinforcing plate 5. An appropriate amount of an epoxy resin 14 is potted at the connecting part of the inner lead 12 as an adhesive resin. Then, the resin is cured at a proper temperature (around 150° C. in this example).

Next, the back face of the semiconductor chip 13 is coated with a silver paste having electrical conductivity as an adhesive resin. In addition, the upper part of the reinforcing plate on the tape is also coated with an adhesive resin 8. Following that, a radiating plate 9 made of copper is arranged over the back face of the semiconductor chip and the upper part of the reinforcing plate to attach the radiating plate 9 to them by curing the resin. After that, by mounting solder balls 10 on the back face of the tape it is possible to obtain a tape type BGA package with low thermal resistance in the same way as in embodiment 1.

As described in the above, the present invention facilitates the scrubbing work in attaching the radiating plate by forming the back face of the semiconductor chip to be more protruded than the reinforcing plate by setting the height of the back face of the semiconductor chip from the substrate surface to be larger by 75±50 μm than the height of the surface of the reinforcing plate from the substrate surface. As a result, it is possible to secure uniform wettability of the back face of the semiconductor chip to the silver paste adhesive, suppress the thickness of the resin to less than 50 μm, and obtain a flip-chip package with low thermal resistance. Moreover, since the gap between the radiating plate and the reinforcing plate can be made to have an appropriate size, it is possible to prevent deformation of the radiating plate attached to the back face of the semiconductor chip.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A semiconductor chip comprising, an insulating substrate, a reinforcing plate in annular shape formed in the periphery on the surface of said insulating substrate, a semiconductor chip formed face down on the surface of said insulating substrate, said reinforcing plate, and a heat radiating plate formed on said semiconductor chip, wherein the height of the back face of said semiconductor chip as measured from the surface of said insulating substrate is larger than the height of the surface of said reinforcing plate, which is brought into contact with said heat radiating plate, as measured from the surface of said insulating substrate.

2. The semiconductor package as claimed in claim 1, wherein the height of the back face of said semiconductor chip as measured from said insulating substrate is larger than the height of the surface of said reinforcing plate as measured from said insulating substrate within the range of 75±50 μm.

3. The semiconductor package as claimed in claim 1, wherein a first adhesive resin is injected to the space between said radiating plate and said semiconductor chip and a second adhesive resin is injected to the space between said radiating plate and said reinforcing plate.

4. The semiconductor package as claimed in claim 3, wherein said first adhesive resin is an electrically conductive resin.

5. A semiconductor package comprising, a TAB type insulating tape, a reinforcing plate formed in annular shape on said insulating tape, a semiconductor chip formed face down on said insulating tape, said reinforcing plate, and a heat radiating plate formed on said semiconductor chip, wherein the height of the back face of said semiconductor chip as measured from said insulating tape is larger than the height of the surface of said reinforcing plate, which is brought into contact with said radiating plate, as measured from said insulating tape.

6. The semiconductor package as claimed in claim 5, wherein the height of the back face of said semiconductor chip as measured from said insulating tape is larger than the height of the surface of said reinforcing plate as measured from said insulating tape within the range of 75±50 μm.
